(19) United States
(12) Patent Application Publication
(10) Pub. No.: US 2014/0264480 A1
(43) Pub. Date: Sep. 18, 2014

(54) SEMICONDUCTOR DEVICE AND METHOD OF FORMING THE SAME

(71) Applicant: UNITED MICROELECTRONICS CORP., Hsin-Chu City (TW)

(72) Inventors: Po-Chao Tsao, New Taipei City (TW); Chien-Ting Lin, Hsinchu City (TW)

(73) Assignee: UNITED MICROELECTRONICS CORP., Hsin-Chu City (TW)

(21) Appl. No.: 13/802,878

(22) Filed: Mar. 14, 2013

(51) Int. Cl. H01L 23/538; H01L 29/78; H01L 29/66

(52) U.S. Cl. CPC H01L 23/5384; H01L 29/66477; H01L 29/78
USPC 257/288; 438/303

(57) ABSTRACT

A method of forming a semiconductor device includes the following steps. At first, a semiconductor substrate is provided, and a metal gate structure and a first dielectric layer are disposed on the semiconductor substrate, wherein a top surface of the metal gate structure is aligned with a top surface of the first dielectric layer. Then, a patterned mask is formed on the metal gate structure, and the patterned mask does not overlap the first dielectric layer. Subsequently, a second dielectric layer covering the patterned mask is conformally formed on the semiconductor substrate. Furthermore, a part of the first dielectric layer and a part of the second dielectric layer are removed for forming at least a contact hole.

### BACKGROUND OF THE INVENTION

1. Field of the Invention

The present invention relates to a semiconductor device and a method of forming the same, and more particularly, to a method of forming a semiconductor device having a patterned mask disposed on the metal gate structure.

2. Description of the Prior Art

Poly-silicon is conventionally used as a gate electrode in semiconductor devices, such as the metal-oxide-semiconductor (MOS). However, with a trend toward scaling down the size of semiconductor devices, the conventional poly-silicon gate has faced problems such as inferior performances due to boron penetration and unavoidable depletion effect which increases the equivalent thickness of the gate dielectric layer, reduces the gate capacitance, and worsens a driving force of the devices. Therefore, work function metals are used to replace the conventional poly-silicon gate to be the metal gate that is suitable for the high-k gate dielectric layer.

In conventional arts, after forming the transistor with a metal gate, a wiring system is formed thereon to electrically connect the metal gate and the source/drain regions, thereby providing signal input/output pathways for the transistor. The wiring system includes a plurality of contact plugs. The conventional method of forming contact plugs includes the following steps. An inter-layer dielectric (ILD) layer is formed to cover the transistor and the source/drain region at two sides of the transistor, then, the ILD layer is patterned to form a plurality of contact holes that expose the source/drain region. Subsequently, a metal layer such as a tungsten (W) layer is deposited into the contact holes to form the contact plugs connected to the source/drain region.

When the critical dimension (CD) of the transistor decreases, the space between the transistors decreases as well, and a location shift of the formed contact holes during the contact plug process may occur more easily, therefore, the later formed contact plugs may simultaneously contact the metal gate and the source/drain regions thereby causing short circuits more frequently, which may induce unexpected electrical performances of the transistor. Consequently, how to improve the manufacturing process of the semiconductor device including the contact plug and the metal gate structure is still an important issue in the field.

### SUMMARY OF THE INVENTION

It is therefore one of the objectives of the present invention to provide a semiconductor device including a patterned mask disposed on the metal gate structure, and a method of forming the same, in order to prevent the contact plug not overlapping the source/drain region from directly contacting the metal gate structure.

According to one exemplary embodiment of the present invention, a method of forming a semiconductor device includes the following steps. At first, a semiconductor substrate is provided, and a metal gate structure and a first dielectric layer are disposed on the semiconductor substrate, wherein a top surface of the metal gate structure is aligned with a top surface of the first dielectric layer. Then, a patterned mask is formed on the metal gate structure, and the patterned mask does not overlap the first dielectric layer. Subsequently, a second dielectric layer covering the patterned mask is conformally formed on the semiconductor substrate. Furthermore, a part of the first dielectric layer and a part of the second dielectric layer are removed for forming at least a contact hole.

According to another exemplary embodiment of the present invention, a semiconductor device is provided. The semiconductor device includes a semiconductor substrate, a metal gate structure, a contact etch stop layer (CESL), an inter-layer dielectric (ILD), a patterned mask and at least a contact plug. The metal gate structure, the CESL and the ILD are disposed on the semiconductor substrate, and the patterned mask is disposed on the metal gate structure. The patterned mask only covers the metal gate structure, and the patterned mask higher than the CESL does not overlap the CESL. Furthermore, the contact plug disposed in the ILD layer partially overlaps the patterned mask and the metal gate structure, and the contact plug has at least a step-shaped side.

In the present invention, the gate conductive layer of the metal gate structure can be totally covered by the patterned mask during the formation of the contact plugs which are electrically connected to the source/drain regions in order to avoid the effects caused by the manufacturing process of the contact plugs. For example, the metal gate structure may not contact the cleaning solution, the etchant or the chemical solvent used in the multiple photolithography processes for forming the contact holes, in order to maintain the material properties of the gate conductive layer of the metal gate structure. Additionally, the manufacturing process of the patterned mask does not include a step of etching back a part of the gate conductive layer, which may prevent from deteriorating the existing defects such as void in the gate conductive layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 through FIG. 2 illustrate a method of forming a semiconductor device according to an exemplary embodiment of the present invention.

FIG. 3 through FIG. 10 illustrate a method of forming a semiconductor device according to a preferred exemplary embodiment of the present invention.

### DETAILED DESCRIPTION

To provide a better understanding of the present invention, preferred exemplary embodiments will be described in detail. The preferred exemplary embodiments of the present invention are illustrated in the accompanying drawings with numbered elements.

In order to prevent a later formed contact plug from directly contacting the metal gate structure, a mask covering the metal gate structure can be formed before forming the contact plug. Please refer to FIG. 1 through FIG. 2, which illustrate a method of forming a semiconductor device according to an exemplary embodiment of the present invention. As shown in FIG. 1, a transistor 12, a contact etch stop layer (CESL) 20 and a dielectric layer 22 are disposed on a semiconductor substrate 10, and the transistor 12 includes a gate dielectric layer 14 and a metal gate 16 disposed between two spacers 18. The method of forming the metal gate 16 includes the replacement metal gate (RMG) process, however, with the decreasing critical dimension (CD) of the transistor 12, the metal material layer (not shown) may not properly fill in the trench (not shown) between the two spacers 18, and defects, such as a void 24, may be formed in the metal gate 16. Subsequently, as shown in FIG. 2, a part of the metal gate 16 is etched back to form a recess (not shown) between two spacers 18, and the recess is later filled with a dielectric material layer (not shown). Furthermore, a chemical mechanism polishing (CMP) process is performed to remove the excessive dielectric material layer outside the recess, and a mask 26 is formed on the remained metal gate 16′. The mask 26 can be used to protect the remaining metal gate 16′, however, the defect in the metal gate 16 may be enhanced during the process of removing a part of the metal gate 16; for example, the void 24 may extend downwards as the etching process is performed, therefore, the occupied space of the void 24 may increase, which may invalidate the transistor 12.

Accordingly, it is noted that a metal gate recess is not preferably formed during the formation of the mask. In other words, the mask is preferably formed on the metal gate structure without metal gate recess. Please refer to FIG. 3 through FIG. 10, which illustrate a method of forming a semiconductor device according to a preferred exemplary embodiment of the present invention. As shown in FIG. 3, a semiconductor substrate 100 is provided, and a plurality of shallow trench isolations (STI) 102 are formed in the semiconductor substrate 100. The semiconductor substrate 100 can be a silicon substrate, an epitaxial silicon substrate, a silicon germanium substrate, a silicon carbide substrate, a silicon-on-insulator (SOI) substrate, or a substrate made of semiconductor material, but is not limited thereto. The STI 102 may include dielectric materials such as silicon oxide, or the STI 102 can be replaced by a dielectric structure such as field oxide (FOX). As the STI processes are known to those skilled in the art, the details are omitted herein for brevity.

At least a transistor 104 and a first dielectric layer 106 are disposed on the semiconductor substrate 100. The transistor 104 includes a metal gate structure 108 and two source/drain regions 110, and the metal gate structure 108 includes a gate dielectric layer 112 and a gate conductive layer 114 sequentially disposed on the semiconductor substrate 100 between two spacers 116, and two source/drain regions 110 are respectively disposed in the semiconductor substrate 100 at two sides of the metal gate structure 108. Various metal gate processes may be used in the present invention, including a gate-first process, a high-k first process integrated into the gate-last process, and a high-k last process integrated into the gate-last process. In this exemplary embodiment, the transistor 104 formed through the high-k last process integrated into the gate-last process is taken for example. The gate dielectric layer 112 including a high-k dielectric layer has a “U-shaped” cross section, and the gate dielectric layer 112 could be made of dielectric materials having dielectric constant (k value) larger than 4. The material of the gate dielectric layer 112 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof. The gate dielectric layer 112 can be formed through an atomic layer deposition (ALD) process or a metal-organic chemical vapor deposition (MOCVD) process, but is not limited thereto. Furthermore, a dielectric layer (not shown) such as a silicon oxide layer can be selectively formed between the substrate 100 and the gate dielectric layer 112. The gate conductive layer 114 contains one or a plurality of metal layers such as a work function metal layer, a barrier layer and low-resistance metal layer. A work function metal layer is formed for tuning the work function of the later formed metal gate structure 108 to be appropriate in an NMOS or PMOS. For an NMOS transistor, the work function metal layer having a work function ranging between 3.9 eV and 4.3 eV may include titanium aluminide (TiAl), zirconium aluminide (ZrAl), tungsten aluminide (WAl), tantalum aluminide (TaAl), or hafnium aluminide (HfAl), but it is not limited thereto. For a PMOS transistor, the work function metal layer having a work function ranging between 4.8 eV and 5.2 eV may include titanium nitride (TiN), tantalum nitride (TaN), tantalum carbide (TaC), but it is not limited thereto.

The method of forming the metal gate structure 108 and the source/drain regions 110 may include the following steps. At first, at least a dummy gate structure (not shown) is formed on the semiconductor substrate 100, and then a spacer 116, the source/drain regions 110, a contact etch stop layer (CESL) 118 and the first dielectric layer 106 are sequentially formed on the substrate 100. The CESL 118 can be selectively disposed between the metal gate structure 108 and the first dielectric layer 106, and the material of the CESL 118 may include dielectric materials such as silicon nitride (SiN), nitrogen doped silicon carbide (NDC). The first dielectric layer 106 can be made of dielectric materials through a spin-on-coating (SOC) process, a chemical vapor deposition (CVD) process or other suitable process, and the dielectric materials include low dielectric constant (low-k) material (k value smaller than 3.9), ultra low-k (ULK) material (k value smaller than 2.6), or porous ULK material, but is not limited thereto. Then, a planarization process such as a chemical mechanical polish (CMP) process or an etching back process is performed to remove a part of the first dielectric layer 106, a part of the CESL 118 and a part of the spacers 116 to expose the dummy gate structure, and then the dummy gate structure is partially removed to form a trench (not shown). Moreover, at least a dielectric material layer (not shown) and at least a metal material layer (not shown) are sequentially filled with the trench, and another chemical mechanical polishing (CMP) process is further performed to remove the dielectric material layer and the metal material layer outside the trench. Accordingly, the metal gate structure 108 including the gate dielectric layer 112 and the gate conductive layer 114 can be formed, and a top surface T1 of the metal gate structure 108 and a top surface T3 of the first dielectric layer 106 are aligned, more specifically, the top surface T1 of the metal gate structure 108, a top surface T2 of the CESL 118 and the top surface T3 of the first dielectric layer 106 are coplanar.

In another exemplary embodiment, as shown in FIG. 4, the gate dielectric layer 112A is formed by a “high-k first” process (that is, the gate dielectric layer is formed before the dummy gate) and therefore has a “-” shape in its cross section, which is different from the “U” shaped gate dielectric layer 112 of the embodiment in FIG. 3, which is formed by a “high-k last” process (that is, the gate dielectric layer is formed after removing the dummy gate). Moreover, the CESL 118 can also include a stress.

In other aspects, the source/drain regions 110 may include doped source/drain regions formed through ion implantation processes, and the shapes of the source/drain regions 110 can be modified according to the stress which is predetermined to be induced to the channel region.

In addition, each component of the transistor can have different embodiments according to different designs of the devices. For example, the source/drain regions can include an epitaxial layer formed by a selective epitaxial growth (SEG) process, wherein the epitaxial layer can be directly formed on the semiconductor substrate 100 such as the source/drain regions 110A shown in FIG. 4, or recesses are previously formed at two sides of the metal gate structure 108 and an epitaxial layer is further formed to fill the recesses such as the source/drain regions 110 shown in FIG. 3, in order to induce stress to the channel region underneath the metal gate structure 108. In this exemplary embodiment, when the transistor 104 serves as an NMOS, the epitaxial layer in the source/drain regions 110 can be made of SiP or SiC to provide tensile stress to the channel region. Furthermore, when the transistor 104 serves as a PMOS, the epitaxial layer in the source/drain regions 110 can be made of SiGe to provide compressive stress to the channel region, but is not limited thereto. Additionally, a dry etching process, a wet etching process or a combination thereof can be performed to form the recesses in various types of shapes, such as a barrel shaped recess, a hexagonal recess or an octagonal recess. Therefore, the epitaxial layer later formed in such recesses may have a hexagonal (also called “sigma Σ”) or an octagonal cross section, in which a flat bottom surface of the epitaxial layer is disposed in the substrate 100 to further enhance the stress effect on the channel region. The embodiments illustrated above are only shown for example. The transistor in the present invention can have a variety of embodiments, which are not described for the sake of simplicity. The following description is based on the transistor 104 of the embodiment shown in FIG. 3.

A patterned mask is further formed on the metal gate structure. The patterned mask disposed on the gate conductive layer and two spacers only covers the metal gate structure without overlapping the first dielectric layer. In other words, the formed patterned mask only contacts the top surface of the metal gate structure, and exposes the top surface of the CESL and the top surface of the first dielectric layer. The method of forming the patterned mask may include the following steps. As shown in FIG. 5 and FIG. 6, a mask material layer 120 is conformally formed on the semiconductor substrate 100, and the mask material layer 120 simultaneously covers the metal gate structure 108, the CESL 118 and the first dielectric layer 106. Subsequently, a mask layer 122 such as a patterned photoresist layer is formed on the mask material layer 120, and the patterned photoresist layer may serve as a mask to perform one or more etching processes to remove a part of the mask material layer 120 and complete the patterned mask 124. Finally, the mask layer 122 such as the patterned photoresist layer is removed. The patterned mask 124 may include a single-layer structure or multi-layer structure, and the material of the patterned mask 124 (i.e. the material of the mask material layer 120) may include a dielectric material such as silicon oxide (SiO), silicon nitride (SiN), silicon carbide (SiC), silicon carbonitride (SiCN), silicon oxynitride (SiON) or a combination thereof.

It is appreciated that, the material of the patterned mask 124 (i.e. a material of the mask material layer 120) is preferably different from the material of the CESL 118 and the material of the first dielectric layer 106. In other words, the mask material layer 120, the CESL 118 and the first dielectric layer 106 may have etching selectivity to each other. More specifically, when the same etchant or slurry is used to remove the mask material layer 120, the CESL 118 and the first dielectric layer 106, a removing rate of the CESL 118 and a removing rate of the first dielectric layer 106 are both substantially lower than a removing rate of the mask material layer 120. Accordingly, after completing the formation of the patterned mask 124, the CESL 118 and the first dielectric layer 106 both still keep most of their original structure. The top surface T1 of the metal gate structure 108 and a bottom surface B1 of the patterned mask 124 contacting the top surface T1 of the metal gate structure 108 may be higher or align with the top surface T2 of the CESL 118 and the top surface T3 of the first dielectric layer 106, and a top surface T4 of the patterned mask 124 is higher than the top surface T2 of the CESL 118 and the top surface T3 of the first dielectric layer 106. In other exemplary embodiments, as the material of the mask material layer is the same as the material of the CESL or the material of the first dielectric layer, a thickness of the mask material layer to be removed can be modulated by a time mode by, for example, adjusting the process conditions such as the processing time of the etching process, in order to totally remove the mask material layer not overlapping the metal gate structure, and stop at the top surface of the CESL and the top surface of the first dielectric layer. Furthermore, during the process of forming the patterned mask 124, the mask material layer 120 totally covers the gate conductive layer 114 and the boundary between the gate conductive layer 114 and each of the spacers 116, therefore, the etchant or the chemical solvent used to remove a part of the mask material layer 120 may be separated from the gate conductive layer 114 to maintain the original structure of the gate conductive layer 114 without the formation of recess between spacers 116, in order to avoid the enhancement of the defect in the gate conductive layer 114, such as avoiding the enlargement of the space occupied by the void in the gate conductive layer. The layout, the size or the shape of the formed patterned mask 124 can be adjusted according to process requirements, therefore, the patterned mask 124 may totally cover the spacers 116 or partially cover the spacers.

As shown in FIG. 7, a second dielectric layer 126 made of dielectric material covering the patterned mask 124, the CESL 118 and the first dielectric layer 106 is conformally formed on the semiconductor substrate 100, and a planarization process is performed on the second dielectric layer 126, therefore, the second dielectric layer 126 has a substantially planar top surface. A material of the second dielectric layer 126 and the material of the first dielectric layer 106 can be the same or different, and the material of the second dielectric layer 126 is preferably different from the material of the patterned mask 124 and the material of the CESL 118. In other words, the second dielectric layer 126, the patterned mask 124 and the CESL 118 may have etching selectivity to each other. Furthermore, as shown in FIG. 8, a part of the first dielectric layer 106 and a part of the second dielectric layer 126 are removed to form at least a contact hole 128/130 in the second dielectric layer 126 and the first dielectric layer 106. The contact holes 128/130 respectively reach the source/drain region 110 at at least a side of the metal gate structure 108. In other words, the contact hole 128/130 may expose a part of the semiconductor substrate 100. Each of the contact holes 128/130 is not limited to a single opening, i.e. the contact holes 128/130 may respectively include a plurality of individual openings or an elongated slot. The slot can extend along a direction parallel to a direction the metal gate structure 108 extends towards to, i.e. the direction perpendicular to the surface of the paper, on the source/drain region 110, in which the slot preferably extends on the overall source/drain region 110, in order to increase the contact surface between the later formed contact plug and the source/drain region 110 and thereby reducing the resistance. In other words, the size, the shape, the number, or the layout of the contact holes 128/130 can be modified according to process requirements. Additionally, the contact holes 128/130 exposing two source/drain regions 110 can be formed in one patterning process with a single mask and a patterned photoresist layer or by the double patterning technique (DPT) process.

The method of forming the contact holes 128/130 may include the following steps, but not limited thereto. At first, a mask (not shown) is formed on the second dielectric layer 126, and the mask preferably is a multi-layered mask that may include an advanced patterning film (APF) such as amorphous carbon layer, a dielectric anti-reflective coating (DARC) layer, a bottom anti-reflective coating (BARC) and a patterned photoresist layer sequentially disposed on the second dielectric layer 126. The APF has a high aspect ratio (HAR), a low line edge roughness (LER) and PR-like ashability, so that it is widely used in semiconductor processes with line widths smaller than 60 nm. Then, the patterned photoresist layer is used as a mask and one or more etching processes, such as an anisotropic dry etching process, are performed to remove the second dielectric layer 126 and the first dielectric layer 106 not covered by the patterned photoresist layer until the CESL 118 is exposed on the source/drain regions 110, and the exposed CESL 118 are further removed to complete the formation of the contact holes 128/130.

In this exemplary embodiment, the material of the patterned mask 124 such as silicon nitride (SiN) and the material of the CESL 118 such as nitrogen doped silicon carbide (NDC) are different from the material of the second dielectric layer 126 such as silicon oxide (SiO) and the material of the first dielectric layer 106 such as silicon oxide (SiO). Accordingly, for the etchant used during the formation of the contact holes 128/130, a removing rate of the second dielectric layer 126 and a removing rate of the first dielectric layer 106 may be substantially larger than a removing rate of the patterned mask 124 and a removing rate of the CESL 118. Moreover, as the sizes of the contact holes are different, for example, a cross-section width W1 of the contact hole 128 is larger than a cross-section width W2 of the contact hole 130, or the formed contact hole shift from the predetermined location, the formed contact hole may partially overlap the metal gate structure 108. F for example, the contact hole 128 can simultaneously expose the source/drain region 110 and the patterned mask 124. Meanwhile, a top surface T5 of the patterned mask 124 exposed by the contact hole 128 is lower than the top surface T4 of the patterned mask 124 still covered by the second dielectric layer 126, and the patterned mask 124 has a non-planar top surface i.e. a top surface constituted by the top surface T5 and the top surface T4. The patterned mask 124 can still totally cover the metal gate structure 108; in other words, the material properties and the thickness of the patterned mask 124 are set to sufficiently maintain the completeness of the metal gate structure 108, and the disposition of the patterned mask 124 is beneficial for increasing the process window of the contact hole process.

After forming the contact holes 128/130, a cleaning process can be optionally performed. For example, argon (Ar) gas is used to clean the surfaces of the contact holes 128/130. Furthermore, a self-aligned metal silicide (salicide) process can be performed to form a metal silicide layer 132 such as a nickel silicide (NiSi) layer on each of the source/drain regions 110 exposed by the contact holes 128/130. In other exemplary embodiments, if the metal silicide layer has been formed on the source/drain regions before forming the openings, this salicide process can be omitted.

A plurality of contact plugs is further formed in the contact holes 128/130. The steps of forming the contact plugs are illustrated below. As shown in FIG. 9, a barrier/adhesive layer 134, a seed layer (not shown) and a conductive layer 136 are sequentially formed on the semiconductor substrate 100, cover the second dielectric layer 126 and fill the contact holes 128/130. The barrier/adhesive layer 134 is formed conformally along the surfaces of the contact holes 128/130, and the conductive layer 136 completely fills the contact holes 128/130. The barrier/adhesive layer 134 could be used for preventing metal elements of the conductive layer 136 from diffusing into the neighboring first dielectric layer 106/second dielectric layer 126, and the barrier/adhesive layer 134 can also increase the adhesion between the conductive layer 136 and the first dielectric layer 106/the second dielectric layer 126. A material of the barrier/adhesive layer 134 can include tantalum (Ta), titanium (Ti), titanium nitride (TiN) or tantalum nitride (TaN) or a suitable combination of metal layers such as Ti/TiO, but is not limited thereto. A material of the seed layer is preferably the same as a material of the conductive layer 136, and a material of the conductive layer 136 can include a variety of low-resistance metal materials, such as aluminum (Al), titanium (Ti), tantalum (Ta), tungsten (W), niobium (Nb), molybdenum (Mo), copper (Cu) or the like, preferably tungsten or copper, and most preferably tungsten, which can form suitable Ohmic contact between the conductive layer 136 and the metal silicide layer 132 or the below source/drain regions 110. Then, a planarization step, such as a chemical mechanical polish (CMP) process or an etching back process or their combination, can be performed to remove the barrier/adhesive layer 134, the seed layer and the conductive layer 136 outside contact holes 128/130, therefore, a top surface of a remaining conductive layer 136 and the top surface of the second dielectric layer 126 are coplanar, and a plurality of the contact plugs 138/140 i.e. the source/drain region contact plugs is completed.

Please refer to FIG. 9 again, the semiconductor device 200 includes the metal gate structure 108, the contact etch stop layer (CESL) 118 and an inter-layer dielectric (ILD) layer 142 constituted by the first dielectric layer 106 and the second dielectric layer 126 disposed on the semiconductor substrate 100, the patterned mask 124 disposed on the metal gate structure 108, and at least a contact plug 138/140 disposed in the ILD layer 142 at a side of the metal gate structure 108. The patterned mask 124 only covers the metal gate structure 108 without overlapping the first dielectric layer 106, the second dielectric layer 126 and the source/drain regions 110. The patterned mask 124 has a non-planar top surface. More specifically, the top surface T4 of the patterned mask 124 covered by the ILD layer 142 is higher than the top surface T5 of the patterned mask 124 not covered by the ILD layer 142. Additionally, the patterned mask 124 is higher than the CESL 118 and does not overlap the CESL 118. In this exemplary embodiment, the CESL 118 between the contact plug 140 and the patterned mask 124 may have an original top surface T2 which is higher than a top surface T6 of the CESL 118 overlapped by the contact plug 138. Furthermore, the top surface T6 of the CESL 118 overlapped by the contact plug 138 is slightly lower than the top surface T5 of the patterned mask 124 overlapped by the contact plug 138. Accordingly, the top surface T1 of the metal gate structure 108 (i.e. a top surface of the gate conductive layer 114) is between the top surface T5 of the patterned mask 124 and the top surface T6 of the CESL 118. Moreover, the contact plug 138 has at least a step-shaped side S, and this step-shaped side S includes a part of the patterned mask 124 and a part of the CESL 118, that is, the patterned mask 124 and the CESL 118 not aligned and exposed by the contact hole 128 as previously shown in FIG. 8.

As shown in FIG. 10, after forming the contact plugs 138/140, a third dielectric layer 144 is further formed on the ILD layer 142, a plurality of second contact plugs 146 are formed in the third dielectric layer 144 to be respectively electrically connected to each of the contact plugs 138/140, and at least a third contact plug 148 is formed in the third dielectric layer 144, a part of the ILD layer 142 (i.e. the second dielectric layer 126) and the patterned mask 124 to be electrically connected to the metal gate structure 108. Furthermore, a conventional metal interconnection fabrication method can be performed. Therefore, a metal interconnect system (not shown), which includes a plurality of inter-metal dielectric (IMD) layers and a plurality of metal layers (so called metal 1, metal 2, and the like) can be further formed above the third dielectric layer 144. The metal interconnection system electrically connects the gate conductive layer 114 of the transistor 104 by the third contact plug 148 and electrically connects the source/drain regions 110 of the transistor 104 by the contact plugs 138/140 and the second contact plugs 146, thereby providing a signal input/output pathway for the transistor 104.

In conclusion, the gate conductive layer of the metal gate structure can be totally covered by the patterned mask during the formation of the contact plugs which are electrically connected to the source/drain regions in order to avoid the effects caused by the manufacturing process of the contact plugs. For example, the metal gate structure may not contact the cleaning solution, the etchant or the chemical solvent used in the multiple photolithography processes for forming the contact holes, in order to keep the material properties of the gate conductive layer of the metal gate structure. Additionally, the manufacturing process of the patterned mask does not include a step of etching back a part of the gate conductive layer, which may prevent from removing the existing defects such as voids in the gate conductive layer.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of forming a semiconductor device, comprising:
providing a semiconductor substrate, wherein a metal gate structure and a first dielectric layer are disposed on the semiconductor substrate, and a top surface of the metal gate structure is aligned with a top surface of the first dielectric layer;
forming a patterned mask on the metal gate structure, wherein the patterned mask does not overlap the first dielectric layer;
conformally forming a second dielectric layer on the semiconductor substrate, wherein the second dielectric layer covers the patterned mask and the first dielectric layer; and
removing a part of the first dielectric layer and a part of the second dielectric layer for forming at least a contact hole.

2. The method of forming a semiconductor device according to claim 1, wherein a bottom surface of the patterned mask contacts the top surface of the metal gate structure.

3. The method of forming a semiconductor device according to claim 1, wherein a method of forming the patterned mask comprises:
conformally forming a mask material layer on the semiconductor substrate; and
forming a patterned photoresist layer on the mask material layer, wherein the patterned photoresist layer serves as a mask to remove a part of the mask material layer.

4. The method of forming a semiconductor device according to claim 1, wherein a material of the patterned mask comprises dielectric material.

5. The method of forming a semiconductor device according to claim 1, wherein further comprising a contact etch stop layer (CESL) disposed between the metal gate structure and the first dielectric layer.

6. The method of forming a semiconductor device according to claim 5, wherein the top surface of the metal gate structure, a top surface of the CESL and the top surface of the first dielectric layer are coplanar.

7. The method of forming a semiconductor device according to claim 5, wherein the patterned mask covers the top surface of the metal gate structure, and exposes a top surface of the CESL and the top surface of the first dielectric layer.

8. The method of forming a semiconductor device according to claim 7, wherein a top surface of the patterned mask is higher than the top surface of the CESL and the top surface of the first dielectric layer.

9. The method of forming a semiconductor device according to claim 5, wherein a material of the CESL is different from a material of the patterned mask.

10. The method of forming a semiconductor device according to claim 1, wherein the metal gate structure comprises a gate dielectric layer and a gate conductive layer sequentially disposed on the semiconductor substrate between two spacers, and the patterned mask is on the gate conductive layer and the spacers.

11. The method of forming a semiconductor device according to claim 1, further comprising forming at least a source/drain region at at least a side of the metal gate structure.

12. The method of forming a semiconductor device according to claim 11, further comprising forming a metal silicide layer on the source/drain region exposed by the contact hole.

13. The method of forming a semiconductor device according to claim 1, wherein the contact hole exposes a part of the semiconductor substrate.

14. A semiconductor device, comprising:
a metal gate structure, a contact etch stop layer (CESL) and an inter-layer dielectric (ILD) layer disposed on a semiconductor substrate;
a patterned mask disposed on the metal gate structure, wherein the patterned mask only covers the metal gate structure, and the patterned mask higher than the CESL does not overlap the CESL; and
at least a contact plug disposed in the ILD layer partially overlapping the patterned mask and the metal gate structure, wherein the contact plug has at least a step-shaped side.

15. The semiconductor device according to claim 14, wherein the step-shaped side comprises a part of the patterned mask and a part of the CESL.

16. The semiconductor device according to claim 14, wherein the metal gate structure comprises a gate dielectric layer and a gate conductive layer sequentially disposed on the semiconductor substrate between two spacers, and the patterned mask is on the gate conductive layer and the spacers.

17. The semiconductor device according to claim 14, wherein the patterned mask comprises a non-planar top surface.

18. The semiconductor device according to claim 17, wherein a top surface of the patterned mask covered by the ILD layer is higher than a top surface of the patterned mask not covered by the ILD layer.

19. The semiconductor device according to claim 14, wherein a top surface of the metal gate structure is between a top surface of the patterned mask and a top surface of the CESL.

20. The semiconductor device according to claim 14, wherein a material of the CESL is different from a material of the patterned mask.
